(19) United States
(12) Patent Application Publication
(10) Pub. No.: US 2007/0285592 A1
(43) Pub. Date: Dec. 13, 2007

(54) System for displaying image and laser annealing method for ltps

(75) Inventors: Yoshihiro Morimoto, Hsinchu City (TW); Ryan Lee, Hualien County (TW); Hanson Liu, Kaohsiung City (TW)

Correspondence Address: BIRCH STEWART KOLASCH & BIRCH, PO BOX 747, FALLS CHURCH, VA, 22040-0747, US

(73) Assignee: TPO DISPLAYS CORP.

(21) Appl. No.: 11/785,206

(22) Filed: Apr. 16, 2007

(30) Foreign Application Priority Data
May 10, 2006 (TW) 095116622

(51) Int. Cl. G02F 1/136; H01L 21/288

(52) U.S. Cl. 349/42; 438/30; 257/E21.174

(57) ABSTRACT

A method for fabricating a system for displaying images is provided, wherein the system comprises a low temperature polysilicon thin film transistor (LTPS-TFT) substrate. The method comprises providing a substrate comprising a first metal layer and a silicon film layer. The silicon film layer is illuminated t by a laser light having a wavelength larger than 400 nm. The silicon film layer is heated to crystallize by absorbing a part of the laser light, and is heated to re-crystallize by absorbing another part of the laser light, which passes through the silicon film layer and is reflected from the first metal layer to the silicon film layer.

### BACKGROUND OF THE INVENTION

1. Field of Invention

The invention relates to a system and an annealing method for polysilicon, and, in particular, to a system for displaying image and a laser annealing method for LTPS.

2. Related Art

With the coming of the digital age, TFT (Thin-Film Transistor) LCDs (Liquid Crystal Displays) have grown quickly to become indispensable electronic products for every person or family.

TFT LCDs may be classified into an amorphous silicon (a-Si) TFT LCD and a LTPS (Low Temperature Polysilicon) TFT LCD according to different liquid crystal panels. The difference between the LTPS TFT display and the a-Si TFT display resides in that the LTPS TFT display uses the LTPS liquid crystal panel and the LTPS TFT display has a polysilicon film layer and thus a better electronic property than the a-Si TFT display. In addition, a TFT array and a peripheral drive circuit can be integrated in the LTPS TFT display, and the flexibility of designing the panel and the circuit may be increased. Therefore, the LTPS TFT display has been gradually valued in the market.

The difference between the processes of manufacturing the LTPS TFT display and the a-Si TFT display is that the LTPS TFT panel needs an additional laser annealing process than the a-Si TFT panel so as to transform the amorphous silicon in the silicon film layer of the transistor into the polysilicon and thus to enhance the carrier mobility of the TFT. The process of manufacturing the conventional LTPS TFT will be described in the following by taking a gate for example. First, as shown in FIG. 1A, a buffer layer 12, a gate 13 and an insulating layer 14 are formed on a glass substrate 11. Next, as shown in FIG. 1B, an amorphous silicon film layer 15 is formed on the gate 13 and the glass substrate 11, and the amorphous silicon film layer 15 is illuminated to melt by excimer laser light EL illuminating by way of ELA (Excimer Laser Annealing). As shown in FIG. 2, the absorptivity of the amorphous silicon with respect to the illuminated excimer laser EL (having a wavelength of 157-400 nm) is proper. In particular, the absorptivity of the amorphous silicon with respect to the illuminated excimer laser EL of XeCl laser (having a wavelength of 308 nm) is 100% (the block portion of FIG. 1B is the absorbing portion) according to the experimental result. Thus, the excimer laser EL cannot pass through the amorphous silicon film layer 15. As shown in FIG. 1C, the amorphous silicon film layer 15 is annealed using the excimer laser to crystallize and transform into a polysilicon film layer 15′. Finally, as shown in FIG. 1D, the polysilicon film layer 15′ is doped to form a source 152, a drain 153 and a channel region 151.

During the ELA process, the excimer laser EL is illuminated on the amorphous silicon film layer 15. Because the illuminating energy is evenly distributed over the amorphous silicon film layer 15, the amorphous silicon film layer 15 gradually becomes a semi-melted state, and a portion of the amorphous silicon serves as a seed for crystallization and then grows into a crystal grain. Accordingly, a polysilicon film layer 15′ with evenly distributed grains having the same smaller size is finally formed. Because the crystal grain of the polysilicon film layer 15′ is too small, the current properties of the TFT are not similar and the carrier mobility of the TFT cannot be improved. In addition, when the excimer laser EL illuminates the amorphous silicon film layer 15, the amorphous silicon close to the gate 13 has smaller crystal grains due to the insufficient thermal energy. This is because that the gate 13 below the amorphous silicon film layer 15 is made of metal and thus has the effect of absorbing heat. However, the polysilicon region of the gate 13 serves as the channel region of the TFT. When the crystal grains of the channel region are too small, the carrier mobility of the TFT will be decreased and the efficiency of the LTPS TFT display will also be influenced.

In addition, the cost of the excimer laser EL is higher and the excimer laser EL has a shorter lifetime and cannot be easily maintained. On the other hand, the dimension of the crystal formed by the annealing process using the excimer laser EL is too small, and the dimensional uniformity of the crystals is poor, so that the carrier mobility of the TFT is greatly influenced.

Thus, it is an important subject of the invention to provide a system for displaying image having larger crystal grains and enhanced carrier mobility, and a LTPS laser annealing method.

### SUMMARY OF THE INVENTION

In view of the foregoing, the invention is to provide a laser annealing method for LTPS capable of enhancing the carrier mobility of the TFT, and a system for displaying image.

An embodiment of a method for fabricating a system for displaying images is provided, wherein the system comprises a low temperature polysilicon thin film transistor (LTPS-TFT) substrate. The method comprises providing a substrate comprising a first metal layer and a silicon film layer. The silicon film layer is illuminated by a laser light having a wavelength larger than 400 nm. The silicon film layer is heated to crystallize by absorbing a part of the laser light, and is heated to crystallize again by absorbing another part of the laser light, which passes through the silicon film layer and is reflected from the first metal layer to the silicon film layer.

A system for display image including an LTPS-TFT substrate is provided. The LTPS-TFT substrate has a substrate, a first metal layer and a polysilicon film layer. The first metal layer and the polysilicon film layer are formed on the substrate. The polysilicon film layer has a first region, a second region and a third region. The first region is located between the second region and the third region and is disposed opposite to the first metal layer, and crystal grains of the first region are larger than crystal grains of the second region and crystal grains of the third region.

As mentioned above, according to the system for displaying image and the method for fabricating the system, the laser light is used for illumination and the first metal layer is used to reflect the laser light such that the silicon film layer absorbs a part of the laser light to crystallize, and the first metal layer reflects another part of the laser light to the first region of the silicon film layer such that the first region is kept at the melted state for a period of time longer than the time when each of the second region and the third region is kept at the melted state. Thus, the crystal grains of the first region are larger than those of the second region and the third region. Then, the silicon film layer is placed to cool the silicon film layer down to the room temperature. In this case, the silicon film layer transforms into the polysilicon film layer after being illuminated by the laser light.

### BRIEF DESCRIPTION OF THE DRAWINGS

The invention will become more fully understood from the detailed description given herein below illustration only, and thus is not limitative of the present invention, and wherein:

FIGS. 1A to 1D are schematic illustrations showing a conventional excimer laser annealing method;

FIG. 2 is a graph showing the relationship between the laser light with different wavelengths and the transmittance ratio of the amorphous silicon according to a preferred embodiment of the invention;

FIG. 3 is a schematic illustration showing the structure of a LTPS-TFT display panel according to the preferred embodiment of the invention;

FIG. 4 is a flow chart showing an annealing method for LTPS according to the preferred embodiment of the invention;

FIGS. 5A to 5E are schematic illustrations showing the annealing method for LTPS and crystal grains of the polysilicon film layer of the LTPS panel according to the preferred embodiment of the invention;

FIG. 6 is a schematic illustration showing the structure of a LTPS panel according to another preferred embodiment of the invention;

FIG. 7 is a schematic illustration showing the structure of a LTPS panel according to still another embodiment of the invention;

FIG. 8 is a schematic illustration showing a liquid crystal display device according to the preferred embodiment of the invention; and

FIG. 9 is a schematic illustration showing a system for displaying image according to the preferred embodiment of the invention.

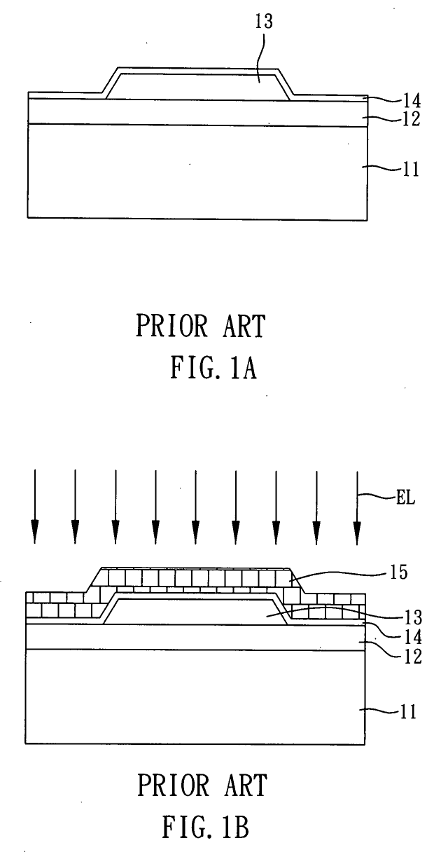

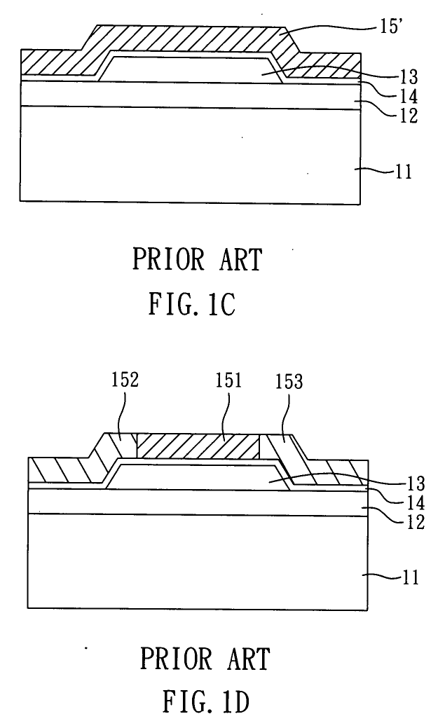

### DETAILED DESCRIPTION OF THE INVENTION

The present invention will be apparent from the following detailed description, which proceeds with reference to the accompanying drawings, wherein the same references relate to the same elements.

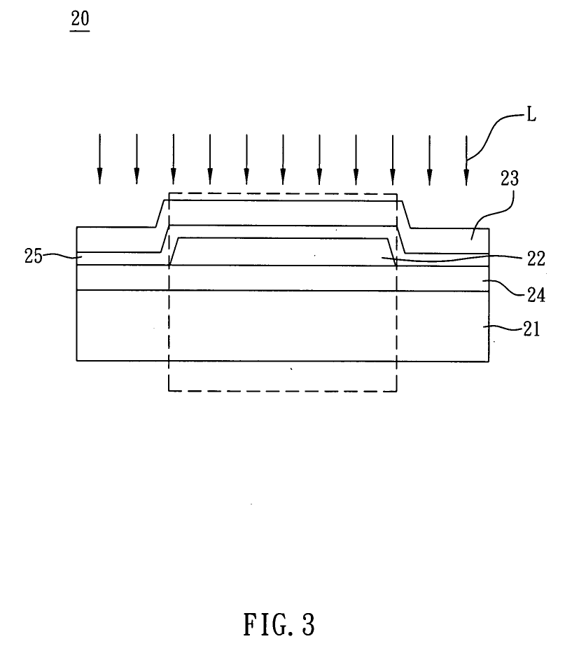

Referring to FIG. 3, an annealing method for LTPS according to an embodiment of the invention is applied to an LTPS-TFT substrate 20. The LTPS-TFT substrate 20 includes a glass substrate 21, a buffer layer 24 formed on the glass substrate 21, a first metal layer 22 disposed on the buffer layer 24, a first insulating layer 25 formed on the first metal layer 22, and a silicon film layer 23 disposed on the first insulating layer 25. The laser light L disposed above the glass substrate illuminates the silicon film layer 23.

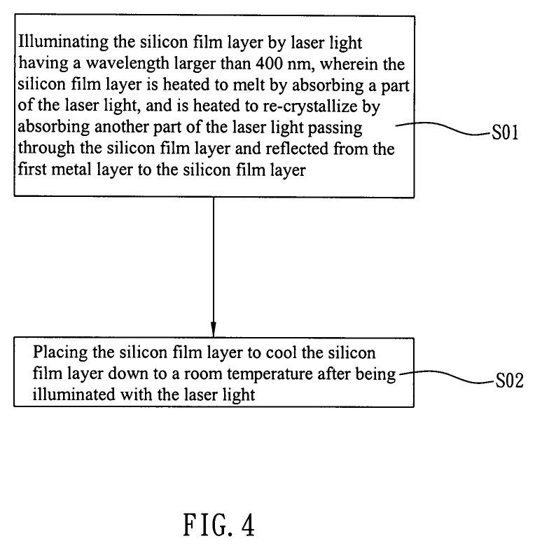

Referring to FIGS. 3 and 4, the annealing method for LTPS includes the following steps. In step S01, the silicon film layer 23 is illuminated by the laser light L having a wavelength larger than 400 nm. The silicon film layer 23 is heated to melt by absorbing a part of the laser light L, and is heated to re-crystallize (the range defined by the dashed lines of FIG. 3) by absorbing another part of the laser light L, which passes through the silicon film layer 23 and is reflected from the first metal layer 22 to the silicon film layer 23. In this embodiment, the laser light L is the solid-state laser light. The portion of the silicon film layer 23, which does not correspond to the first metal layer 22, absorbs one part of the laser light L. The other part of the laser light L passes through silicon film layer 23 and is not reflected.

In step S02, the silicon film layer 23 is placed to cool the silicon film layer 23 down to the room temperature after being illuminated by the laser light L.

Finally, the silicon film layer 23 crystallizes and transforms into a polysilicon film layer after the laser annealing process.

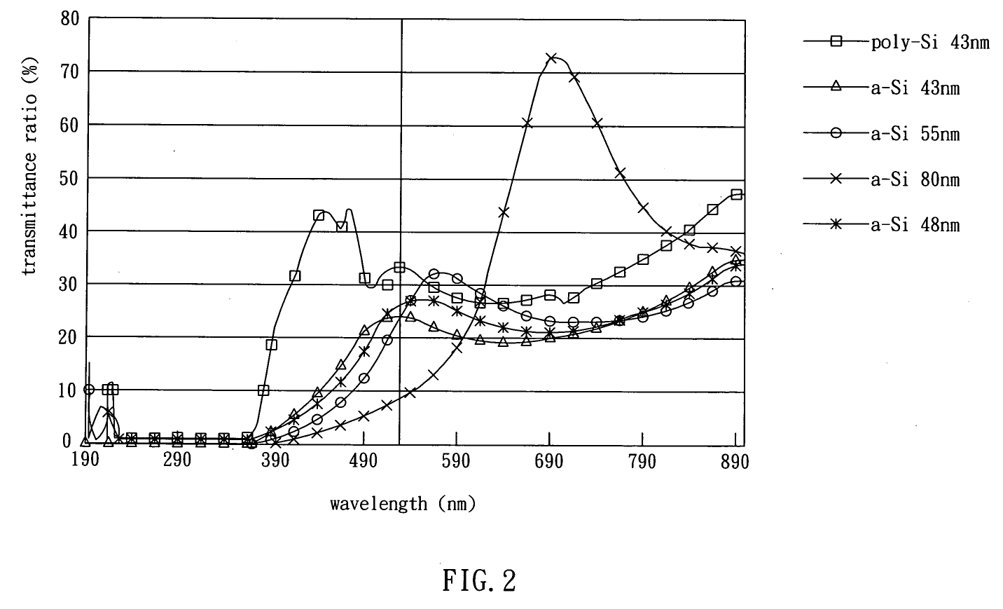

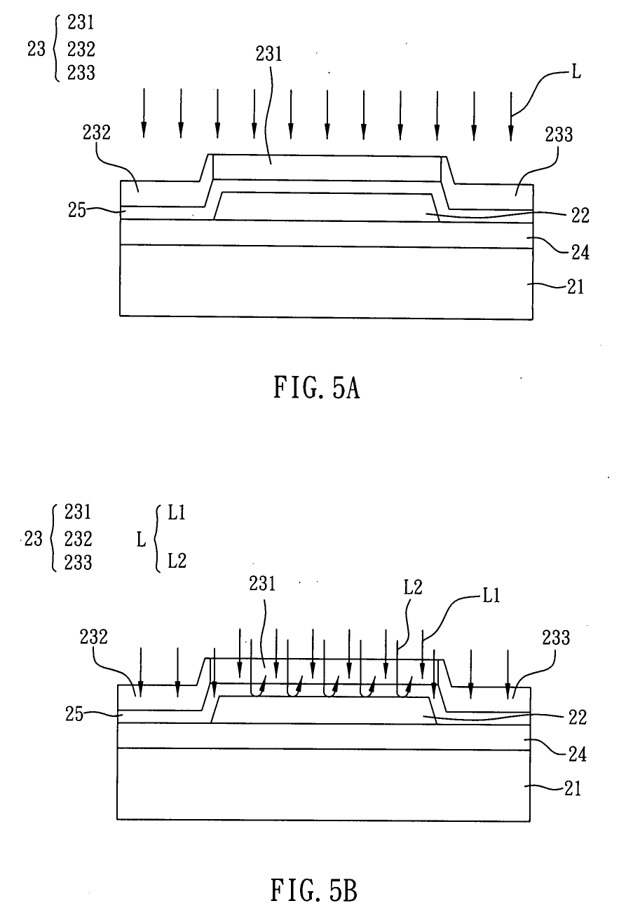

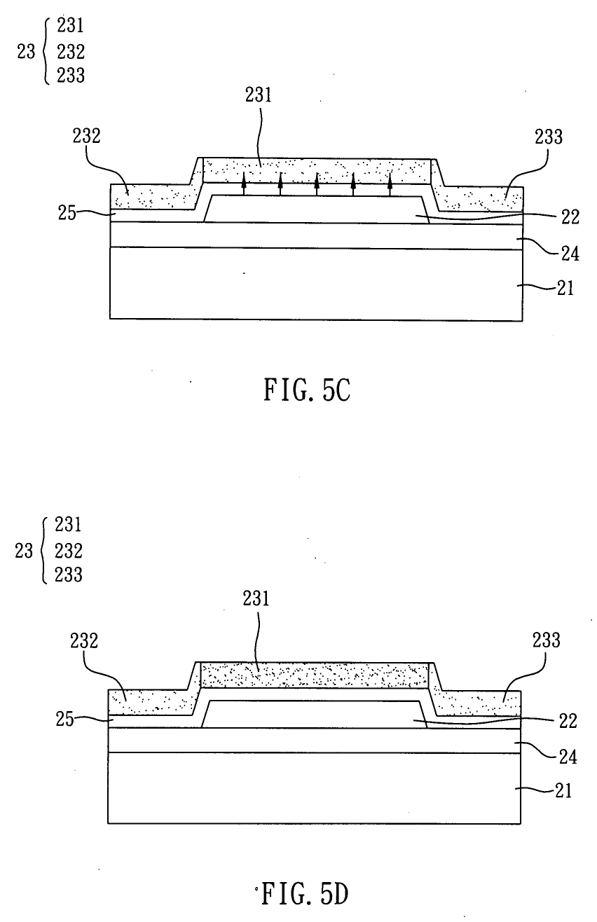

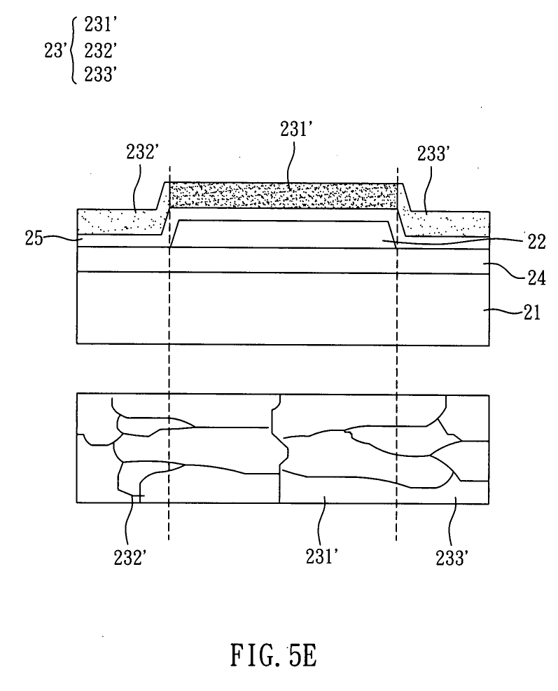

In addition, in order to make the invention be more easily understood, the annealing method for LTPS of this embodiment will be described with reference to the steps of FIGS. 5A to 5E. Referring to FIGS. 4 and 5A, the silicon film layer 23 of this embodiment has a first region 231, a second region 232 and a third region 233. The first region 231 is located between the second region 232 and the third region 233, and it is disposed opposite to the first metal layer 22. The thickness of the first metal layer 22 is larger than 100 angstroms such that the first metal layer 22 can reflect the laser light L. The laser light L includes one part L1 of the laser light and the other part L2 of the laser light. When the laser light L illuminates the silicon film layer 23, the first region 231, the second region 232 and the third region 233 are heated by the illumination of the laser light L. Then, the first region 231, the second region 232 and the third region 233 are melted and start to crystallize. However, because the solid-state laser light is applied, the amorphous silicon has a poor laser absorptivity with respect to the laser light having the wavelength above 400 nm as shown in FIG. 2. Thus, the silicon film layer 23 only absorbs a part L1 of the laser light.

As shown in FIG. 5B, the first region 231 absorbs the part L1 of the laser light to crystallize, and the other part L2 of the laser light passes through the first region 231 and illuminates the first metal layer 22. Because the thickness of the first metal layer 22 is large enough, the laser light L cannot penetrate through the first metal layer 22. Instead, the other part L2 of the laser light can be reflected to the first region 231 by the first metal layer 22. As shown in FIGS. 5C and 5D, the first region 231 absorbs the other part L2 of the reflected laser light to heat the first region 231. Such that the first region 231 is kept melted for a period of time, which is longer than the time when each of the second region and the third region is kept melted, and the first region 231 is re-crystallized after the annealing process. As shown in FIG. 5B, when the laser light L illuminates the second region 232 and the third region 233, the part L1 of the laser light is also absorbed by the second region 232 and the third region 233. The other part L2 of the laser light passes through the second region 232 and the third region 233, and it is not reflected because the second region 232 and the third region 233 are not disposed above the first metal layer 22. The second region 232 and the third region 233 are heated to melt and to crystallize. Finally, as shown in FIG. 5E, the silicon film layer 23 transforms from the amorphous silicon into a polysilicon film layer 23′ after the annealing process. Thus, the first region 231 of amorphous silicon transforms into the first region 231′ of polysilicon after it is melted and re-crystallized. The second region 232 and the third region 233 of amorphous silicon also transform into a second region 232′ and a third region 233′ of polysilicon.

Referring again to FIG. 5E, because the first region 231′ almost completely absorbs the laser light L, the crystal grains of the first region 231′ are larger than those of the second region 232′ and the third region 233′. Furthermore, because the first metal layer 22 reflects the laser light L to the first region 231′, the part of the first region 231′ adjacent to the first metal layer 22 is illuminated and heated to crystallize, and it thus gets a longer period of melting time than the other part of the first region 231′. Thus, the crystal grains of the part of the first region 231′ adjacent to the first metal layer 22 absorb much more energy of the laser light L than those of the other part of the first region 231′. Accordingly, the crystal grains of the one part of the first region 231′ adjacent to the first metal layer 22 are also larger than the crystal grains of the other part of the first region 231′. Finally, a TFT is formed by way of doping after the annealing method for LTPS. In this embodiment, the first metal layer 22 is the gate of the transistor, the second region 232′ and the third region 233′ are respectively the source and the drain of the transistor, and the first region 231′ is the channel region of the transistor.

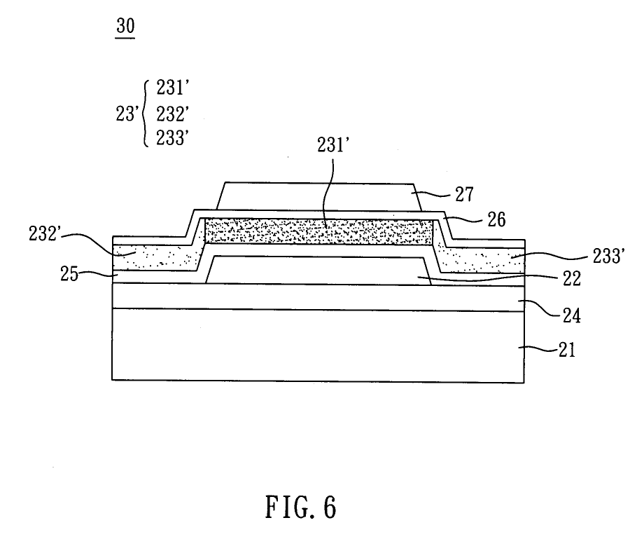

FIG. 6 is a schematic illustration showing the structure of an LTPS-TPT substrate 30 according to another embodiment of the invention. After the annealing method (FIG. 5E), a second insulating layer 26 is disposed on the polysilicon film layer 23′ and a second metal layer 27 is disposed on the second insulating layer 26 such that another aspect of manufacturing process is built. Then, a TFT is formed by way of doping. Herein, the first metal layer 22 and the second metal layer 27 serve as the gate of the transistor, the second region 232′ and the third region 233′ are respectively the source and the drain of the transistor, and the first region 231′ is the channel region of the transistor. Besides, in other embodiments, the first metal layer 22 is light shading metal and the second metal layer serves as the gate.

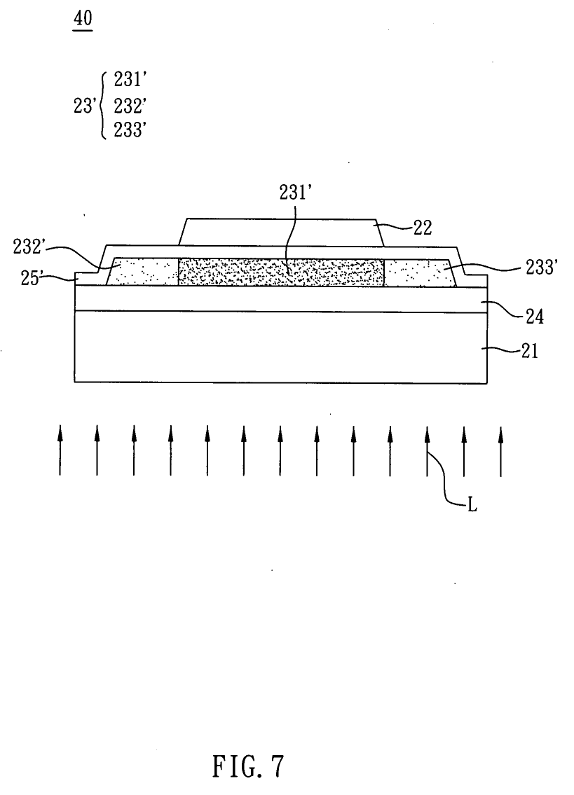

FIG. 7 is a schematic illustration showing the structure of an LTPS-TFT substrate 40 according to still another embodiment of the invention. In this structure, the buffer layer 24 is formed on the glass substrate 21, the polysilicon film layer 23′ is disposed on the buffer layer 24, an insulating layer 25′ is disposed on the polysilicon film layer 23′, and then the first metal layer 22 is disposed on the insulating layer 25′. When the laser annealing method is being performed, the laser light L below the glass substrate 21 illuminates the silicon film layer 23. The silicon film layer 23 transforms into the polysilicon film layer 23′ after the annealing method is performed. Finally, a TFT is formed by way of doping. In this case, the first metal layer 22 is the gate of the transistor, the second region 232′ and the third region 233′ are respectively the source and the drain of the transistor, and the first region 231′ is the channel region of the transistor.

Because the laser light L is used for illumination, the silicon film layer 23 of amorphous silicon crystallizes and transforms into the polysilicon film layer 23′. Then, the crystallized first region 231 of the silicon film layer 23 is re-crystallized because the first metal layer 22 reflects the laser light L. Thus, the crystal grains of the first region 231′ after the annealing process not only get larger but may also be distributed over the first region 231′ more evenly, such that the carrier mobility of the transistor is enhanced.

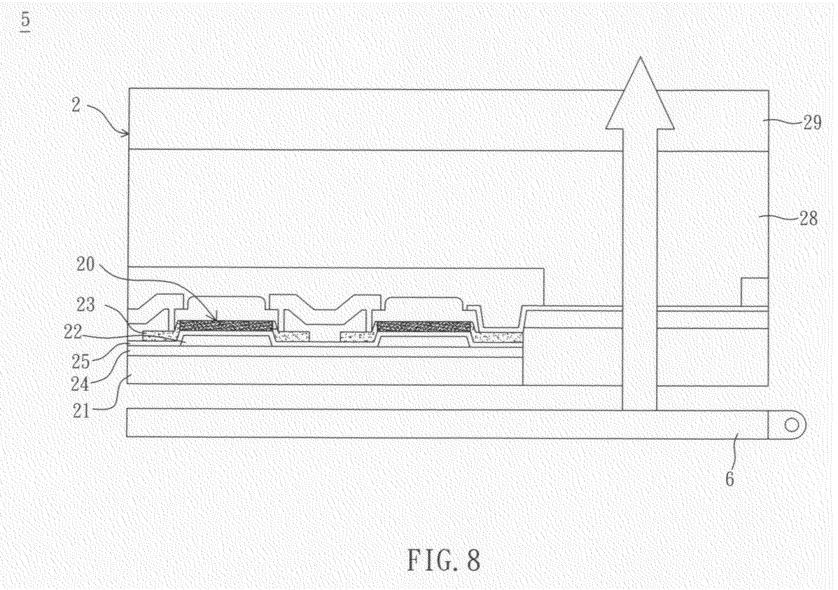

FIG. 8 is a schematic illustration showing a system for displaying image according to the various embodiments of the invention. The system includes a liquid crystal display device 5. Referring to FIG. 8, the liquid crystal display device has an LTPS-TFT display panel 2 and a backlight module 6, which is disposed at one side of the LTPS-TFT display panel 2.

The LTPS-TFT display panel 2 has the LTPS-TFT substrate 20, a liquid crystal layer 28 and a color filter substrate 29. In the embodiment, the LTPS-TFT substrate 20 has the glass substrate 21, the first metal layer 22, the polysilicon film layer 23′. The first metal layer 22 and a polysilicon film layer 23′ are formed on the glass substrate 21, and the liquid crystal layer 28 and the color filter substrate 29 are formed on the polysilicon film layer.

The liquid crystal display device 5 of this embodiment uses the backlight module 6 as the light source, as indicated by the arrow of FIG. 8. The light coming from the light source passes through the LTPS-TFT substrate 20, the liquid crystal layer 28 and the color filter substrate 29. Thus the liquid crystal display device displays images. Because the liquid crystal display device 5 comprises the LTPS-TFT display panel 2, the carrier mobility is enhanced, the electroconductivity is good, the power may be saved, and the displayed image looks better.

The LTPS-TFT substrate 20 is characterized in that the polysilicon film layer has a first region, a second region and a third region. The first region is located between the second region and the third region and disposed opposite to the first metal layer. The crystal grains of the first region are larger than those of the second region and the third region. The LTPS-TFT display panel of this embodiment is manufactured according to the annealing method for LTPS, as shown in FIGS. 4 and 5A to 5E, and detailed descriptions thereof are omitted.

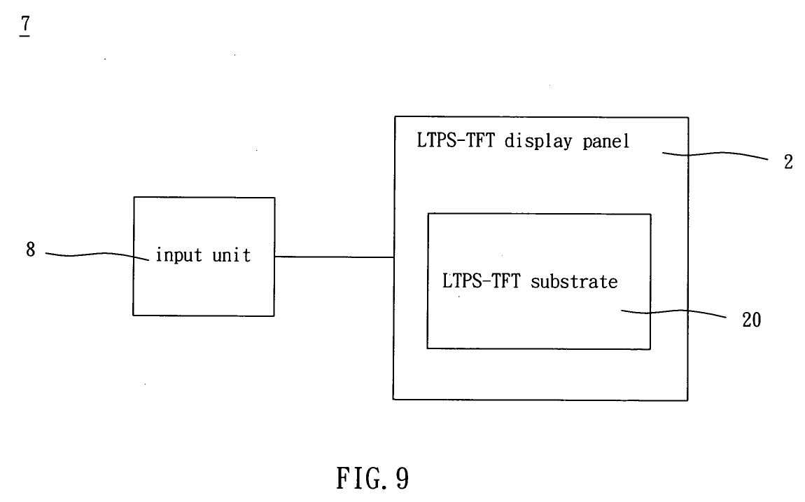

FIG. 9 is a schematic illustration showing a system for displaying image according to the preferred embodiment of the invention. The system further includes an electronic device 7. The electronic device 7 includes the LTPS-TFT display panel 2 and an input unit 8. The input unit 8 is coupled to the LTPS-TFT display panel 2 and provides input signals (e.g., an image signal) to the LTPS-TFT display panel 2 to generate images. The electronic device 7 may be a mobile phone, digital camera, PDA (personal data assistant), notebook computer, desktop computer, television, car display, or portable DVD player, for example.

In summary, according to the system for displaying image and the laser annealing method for LTPS, the laser light is used for illumination and the first metal layer is used to reflect the laser light such that the silicon film layer absorbs a part of the laser light to crystallize, and the first metal layer reflects another part of the laser light to the first region of the silicon film layer such that the first region is kept at the melted state for a period of time longer than the time when each of the second region and the third region is kept at the melted state. Thus, the crystal particles of the first region are larger than those of the second region and the third region. Then, the silicon film layer is placed to cool the silicon film layer down to the room temperature. In this case, the silicon film layer transforms into the polysilicon film layer after being illuminated by the laser light. Compared with the prior art, because the first metal layer can reflects a part of the laser light, which is not absorbed by the silicon film layer, back to the silicon film layer, so that the silicon film layer can further absorb the reflected light. After several times of absorption and reflection, the energy of the laser light is almost absorbed by the silicon film layer. Thus, the usage of the laser light is enhanced, and the cost can be decreased because the solid-state laser light is used. The first region of the silicon film layer also absorbs the laser light several times and is thus heated, so that the melting time of the first region is lengthened. Accordingly, the crystallized first region obtains larger and smoother crystal particles and the polysilicon film layer with a lower defect density. Furthermore, the electron mobility of the TFT can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An method for fabricating a system for displaying images wherein the system comprises a low temperature polysilicon thin film transistor (LTPS-TFT) substrate, the method comprising:
providing a substrate comprising a first metal layer and a silicon film layer; and
illuminating the silicon film layer by laser light having a wavelength larger than 400 nm, wherein the silicon film layer is heated to crystallize by absorbing a part of the laser light, and is heated to crystallize again by absorbing another part of the laser light passing through the silicon film layer and reflected from the first metal layer to the silicon film layer.

2. The method according to claim 1, wherein:
the silicon film layer has a first region, a second region and a third region;
the first region, the second region and the third region crystallize after being illuminated by the laser light;
the first region is located between the second region and the third region, is disposed opposite to the first metal layer, and is re-crystallized by absorbing the laser light reflected by the first metal layer; and
crystal grains of the first region after crystallization by absorbing the laser light reflected by the first metal layer are larger than crystal grains of the second region and crystal grains of the third region.

3. The method according to claim 2, wherein a portion of the crystal grains of the first region abutting the first metal layer is larger than any other portion of the crystal grains of the first region.

4. The method according to claim 2, wherein the first metal layer, the second region and the third region are respectively a gate, a source and a drain of a transistor, and the first region is a channel region of the transistor.

5. The method according to claim 1, further comprising:
forming a first insulating layer on the first metal layer, wherein the silicon film layer is disposed on the first insulating layer.

6. The method according to claim 5, further comprising:
forming a second metal layer and a second insulating layer on the silicon film layer, wherein the second metal layer is disposed on the second insulating layer.

7. The method according to claim 1, further comprising:
forming an insulating layer on the silicon film layer, wherein the first metal layer is disposed on the insulating layer.

8. The method according to claim 1, wherein a thickness of the first metal layer is larger than 100 angstroms.

9. The method according to claim 1, wherein the laser light is a solid-state laser light.

10. A system for displaying image, comprising:
an LTPS-TFT substrate having a substrate, a first metal layer and a polysilicon film layer, wherein the first metal layer and the polysilicon film layer are formed on the substrate, the polysilicon film layer has a first region, a second region and a third region, the first region is located between the second region and the third region and is disposed opposite to the first metal layer, and crystal grains of the first region are larger than crystal grains of the second region and crystal grains of the third region.

11. The system according to claim 10, wherein after the polysilicon film layer is annealed by laser light, the crystal grains of the first region are larger than the crystal grains of the second region and the third region.

12. The system according to claim 10, wherein a portion of the crystal grains of the first region abutting the first metal layer is larger than any other portion of the crystal grains of the first region.

13. The system according to claim 10, wherein the first metal layer, the second region and the third region are respectively a gate, a source and a drain of a transistor, and the first region is a channel region of the transistor.

14. The system according to claim 10, further comprising:
a first insulating layer, wherein the first metal layer is disposed on the substrate, the first insulating layer is disposed on the first metal layer, and the polysilicon film layer is disposed on the first insulating layer.

15. The system according to claim 14, further comprising:
a second insulating layer disposed on the polysilicon film layer; and
a second metal layer disposed on the second insulating layer.

16. The system according to claim 10, further comprising:
an insulating layer, wherein the polysilicon film layer is disposed on the substrate, the insulating layer is disposed on the polysilicon film layer, and the first metal layer is disposed on the insulating layer.

17. The system according to claim 10, wherein a thickness of the first metal layer is larger than 100 angstroms.

18. The system according to claim 10, further comprising:
a liquid crystal display device having a LTPS-TFT display panel and a backlight module disposed at one side of the LTPS-TFT display panel, wherein the LTPS-TFT display panel has the LTPS-TFT substrate.

19. The system according to claim 10, further comprising:
an electronic device having a LTPS-TFT display panel and an input unit, wherein the LTPS-TFT display panel has the LTPS-TFT substrate, and the input unit is coupled to the LTPS-TFT display panel and provides input signals to the LTPS-TFT display panel to generate images.

20. The system according to claim 19, wherein the electronic device is a mobile phone, a digital camera, a PDA (personal data assistant), a notebook computer, a desktop computer, a television, a car display, or a portable DVD player.
